(19) United States
(12) Patent Application Publication
(10) Pub. No.: US 2025/0391676 A1
(43) Pub. Date: Dec. 25, 2025

(54) SUBSTRATE PROCESSING APPARATUS

(71) Applicant: SAMSUNG ELECTRONICS CO., LTD., Suwon-si (KR)

(72) Inventors: Hyunwoo LIM, Suwon-si (KR); Mincheol Park, Suwon-si (KR); Sooho Choi, Suwon-si (KR); Yunhee Choi, Suwon-si (KR)

(73) Assignee: SAMSUNG ELECTRONICS CO., LTD., Suwon-si (KR)

(21) Appl. No.: 18/987,708

(22) Filed: Dec. 19, 2024

(30) Foreign Application Priority Data
Jun. 24, 2024 (KR) 10-2024-0082174

(51) Int. Cl. H01L 21/67

(52) U.S. Cl. CPC H01L 21/67069

(57) ABSTRACT

A substrate processing apparatus may include: a chamber; a support in the chamber and configured to support a substrate; and a gas mixer connected to the chamber and configured to spray a process gas into the chamber. The gas mixer may include: division partition walls spaced apart in a vertical direction; and mixing flow paths oriented in the vertical direction in the division partition walls.

### CROSS-REFERENCE TO RELATED APPLICATION

This application claims priority to and the benefit of Korean Patent Application No. 10-2024-0082174 filed in the Korean Intellectual Property Office on Jun. 24, 2024, the entire contents of which are incorporated herein by reference.

### BACKGROUND

### 1. Field

The present disclosure relates to a substrate processing apparatus.

### 2. Description of Related Art

Various processes, such as photolithography, etching, ashing, ion implantation, thin-film deposition, and cleaning, are performed on a substrate to form desired patterns on the substrate in order to manufacture semiconductor elements.

Process gases may be used for the substrate processing process. Two or more types of process gases may be supplied together and used to process the substrate. In this case, the two or more types of process gases may be reactive to one another. In this case, in case that the two or more types of process gases are mixed in advance, efficiency in processing the substrate may deteriorate.

### SUMMARY

The present disclosure attempts to provide a substrate processing apparatus capable of effectively supplying process gases into a chamber.

However, the object to be achieved by the one or more embodiments of the present disclosure is not limited to the above-mentioned object but may be variously expanded without departing from the technical spirit of the present disclosure.

According to one or more example embodiments, a substrate processing apparatus may include: a chamber; a support in the chamber and configured to support a substrate; and a gas mixer connected to the chamber and configured to spray a process gas into the chamber. The gas mixer may include: division partition walls spaced apart in a vertical direction; and mixing flow paths oriented in the vertical direction in the division partition walls.

According to one or more example embodiments, a substrate processing apparatus may include: a chamber; a support in the chamber and configured to support a substrate; and a gas mixer connected to the chamber and configured to spray a process gas into the chamber. The gas mixer may include: a housing having an accommodation space positioned therein; and a gas mixing member disposed in the accommodation space. The gas mixing member may include: division partition walls spaced apart in a vertical direction; and a guide column connecting the division partition walls.

According to one or more example embodiments, a substrate processing apparatus may include: a chamber; a support in the chamber and configured to support a substrate; a gas mixer connected to the chamber and configured to spray a process gas into the chamber; a first process gas supply connected to the gas mixer and configured to supply a first process gas; and a second process gas supply connected to the gas mixer and configured to supply a second process gas. The gas mixer may include: a housing having an accommodation space therein; and a gas mixing member in the accommodation space. The gas mixing member may include: division partition walls spaced apart in a vertical direction; and a guide column connecting the division partition walls.

According to the one or more embodiments, it is possible to provide a substrate processing apparatus capable of effectively supplying the process gases into the chamber.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a view illustrating a substrate processing apparatus according to one or more embodiments;

FIG. 2 is a view illustrating a gas mixing module in FIG. 1 according to one or more embodiments;

FIG. 3 is a view illustrating a module housing of the gas mixing module according to one or more embodiments;

FIG. 4 is a view illustrating a gas mixing member of the gas mixing module according to one or more embodiments;

FIG. 5 is a transverse cross-sectional view taken in a direction perpendicular to an upward/downward direction of a region in which a guide column is disposed according to one or more embodiments;

FIG. 6 is a view illustrating a flow state of a process gas occurring around the gas mixing member when the process gas is supplied to the gas mixing module according to one or more embodiments;

FIG. 7 is a view illustrating a flow state of the process gas in a cross-section corresponding to FIG. 5 according to one or more embodiments;

FIG. 8 is a transverse cross-sectional view of a region in which a guide column of a gas mixing member according to one or more embodiments is disposed;

FIG. 9 is a transverse cross-sectional view of a region in which a guide column of a gas mixing member according to still one or more embodiments is disposed;

FIG. 10 is a transverse cross-sectional view of a region in which a guide column of a gas mixing member according to yet one or more embodiments is disposed;

FIG. 11 is a view illustrating a gas mixing module according to one or more embodiments;

FIG. 12 is a view illustrating a substrate processing apparatus according to one or more embodiments; and

FIG. 13 is a view illustrating a substrate processing apparatus according to still one or more embodiments.

### DETAILED DESCRIPTION

Hereinafter, one or more embodiments of the present disclosure will be described in detail with reference to the accompanying drawings so that those with ordinary skill in the art to which the present disclosure pertains may easily carry out the one or more embodiments. The present disclosure may be implemented in various different ways and is not limited to the one or more embodiments described herein.

A part irrelevant to the description will be omitted to clearly describe the present disclosure, and the same or similar constituent elements will be designated by the same reference numerals throughout the specification.

In addition, a size and thickness of each constituent element illustrated in the drawings are arbitrarily shown for convenience of description, but the present disclosure is not limited thereto. In order to clearly describe several layers and regions, thicknesses thereof are enlarged in the drawings. In the drawings, the thicknesses of some layers and regions are exaggerated for convenience of description.

In addition, when one component such as a layer, a film, an area, or a plate is described as being positioned “above” or “on” another component, one component can be positioned “directly on” another component, and one component can also be positioned on another component with other components interposed therebetween. On the contrary, when one component is described as being positioned “directly above” another component, there is no component therebetween. In addition, when a component is described as being positioned “above” or “on” a reference part, the component may be positioned “above” or “below” the reference part, and this configuration does not necessarily mean that the component is positioned “above” or “on” the reference part in a direction opposite to gravity.

Throughout the specification, unless explicitly described to the contrary, the word “comprise/include” and variations such as “comprises/includes” or “comprising/including” will be understood to imply the inclusion of stated elements, not the exclusion of any other elements.

In addition, throughout the specification, the phrase “in a plan view” means when an object is viewed from above, and the phrase “in a cross-sectional view” means when a cross section made by vertically cutting an object is viewed from a lateral side.

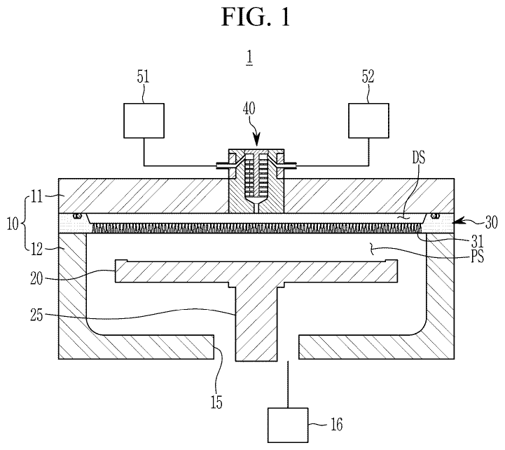

FIG. 1 is a view illustrating a substrate processing apparatus 1 according to an one or more embodiments.

With reference to FIG. 1, the substrate processing apparatus 1 according to the one or more embodiments may include a chamber 10, a support member 20, a shower head 30, and a gas mixing module 40.

The substrate processing apparatus 1 processes a substrate by using process gases. For example, the substrate processing apparatus 1 may perform a process of removing a natural oxide film from the substrate by using reactivity of the process gas. The substrate may be a wafer or the like used to manufacture a semiconductor element.

The chamber 10 provides therein a process space PS in which a substrate processing process is performed. The chamber 10 may be made of metal. For example, the chamber 10 may be made of aluminum. The chamber 10 may be grounded. In the chamber 10, a region positioned at a lower side of the process space PS based on a vertical direction may be referred to as a lower wall of the chamber 10. Further, in the chamber 10, a region positioned at a upper side of the process space PS in the vertical direction may be referred to as an upper wall of the chamber 10. Therefore, the chamber 10 may be configured such that a bottom surface of the upper wall and an upper surface of the lower wall are directed toward a space positioned in the chamber 10.

An exhaust hole 15 may be positioned at one side of the chamber 10. The exhaust hole 15 may be positioned in a lower region of the chamber 10. The exhaust hole 15 may be positioned in the lower wall of the chamber 10. Reaction by-products, which are generated during a processing procedure, and gases, which remain in the internal space of the chamber 10, may be discharged to the outside through the exhaust hole 15. The pressure in the chamber 10 may be lowered to predetermined pressure by an exhaust process. An exhaust member 16 may be connected to the exhaust hole 15. The exhaust member 16 applies negative pressure for discharging gases in the chamber 10. In addition, the exhaust member 16 may adjust a flow rate of the gas to be discharged through the exhaust hole 15. The exhaust member 16 may include at least one pump. In addition, the exhaust member 16 may include a valve or the like and adjust a flow rate of the gas to be discharged through the exhaust hole 15 in accordance with an opening degree of the valve.

The support member 20 is disposed in the chamber 10. The support member 20 supports the substrate. For example, the support member 20 may be connected and fixed to a support shaft 25. The support shaft 25 may be provided such that a longitudinal direction thereof is directed toward the upward/downward (vertical) direction, such that the support shaft 25 is disposed to pass through the exhaust hole 15. An upper portion of the support shaft 25 may be connected to the support member 20 in the chamber 10. The exhaust hole 15 may be provided to be larger than an outer periphery of the support shaft 25, such that the gas in the chamber 10 may be discharged through a space positioned between the support shaft 25 and the exhaust hole 15.

The support member 20 may be configured to cool the substrate. For example, a cooling flow path may be positioned in the support member 20. Therefore, the support member 20 may be cooled by a refrigerant flowing through the cooling flow path, such that the substrate positioned on the support member 20 may be cooled.

The shower head 30 may include an upper surface directed (oriented) in an upward direction, and bottom surface directed in a downward direction. The bottom surface of the shower head 30 is positioned to be directed toward the inside of the chamber 10. The shower head 30 may disperse and spray the process gas, which is supplied into the chamber 10, toward the process space PS positioned above the support member 20. The shower head 30 may be fixed to the chamber 10. For example, the chamber 10 may include an upper chamber member 11 and a lower chamber member 12. The upper chamber member 11 may be connected to the lower chamber member 12 so that the upper chamber member 11 is positioned above the lower chamber member 12. Further, a partial region of the shower head 30 has a structure interposed between the upper chamber member 11 and the lower chamber member 12 and fixed to the chamber 10.

A process gas flow path 31 may be positioned in the shower head 30. The process gas flow path 31 may be connected to the bottom surface of the shower head 30. The process gas flow path 31 may include hole structures directed in the upward/downward direction. In addition, the process gas flow path 31 may also include a section that connects the hole structures directed in the upward/downward direction.

The upper surface of the shower head 30 is positioned to be spaced apart from the bottom surface of the upper wall of the chamber 10, such that a gas distribution space DS may be positioned between the upper surface of the shower head 30 and the bottom surface of the upper wall of the chamber 10. The gas distribution space DS may be connected to the process gas flow path 31. In addition, the upper surface of the shower head 30 and the bottom surface of the upper wall of the chamber 10 may be positioned to be in contact with each other.

The gas mixing module 40 may be connected to the chamber 10. For example, the gas mixing module 40 may be connected to a central region of the upper wall of the chamber 10. The gas mixing module 40 is disposed to penetrate the upper chamber member 11 of the chamber 10, such that a bottom surface of the gas mixing module 40 may be positioned to be exposed to the inside of the chamber 10.

The gas mixing module 40 sprays the process gas into the chamber 10. The process gas sprayed from the gas mixing module 40 may be supplied to the process space PS through the gas distribution space DS and the process gas flow path 31 of the shower head 30. In addition, in case that the gas distribution space DS is excluded, the process gas sprayed from the gas mixing module 40 may be introduced directly into the process gas flow path 31 of the shower head 30.

The gas mixing module 40 may be connected to process gas supply members 51 and 52. The process gas supply members 51 and 52 supply the process gases to the gas mixing module 40. The process gas supply members 51 and 52 may include a first process gas supply member 51 and a second process gas supply member 52. The first process gas supply member 51 may be connected to the gas mixing module 40 and supply a first process gas to the gas mixing module 40. For example, the first process gas may be ammonia gas or the like. The first process gas supply member 51 may supply the first process gas in a state of being mixed with a carrier gas. The carrier gas may be an inert gas such as argon gas.

The second process gas supply member 52 may be connected to the gas mixing module 40 may supply a second process gas to the gas mixing module 40. For example, the second process gas may be hydrogen fluoride gas or the like. The second process gas supply member 52 may supply the second process gas in a state of being mixed with a carrier gas. The carrier gas may be an inert gas such as argon gas.

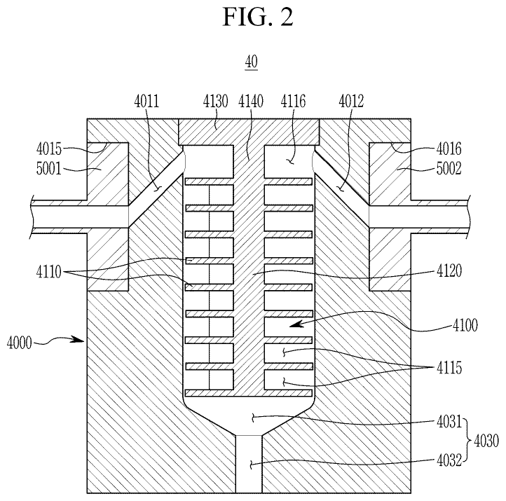

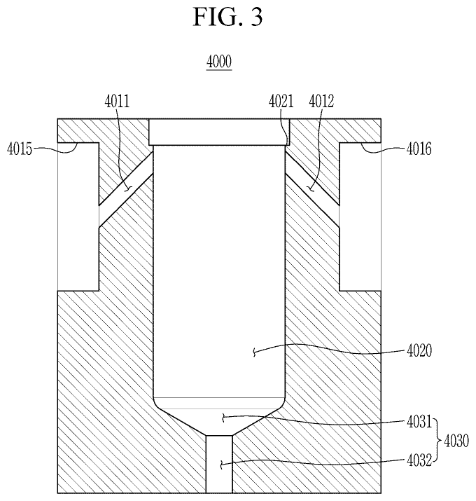

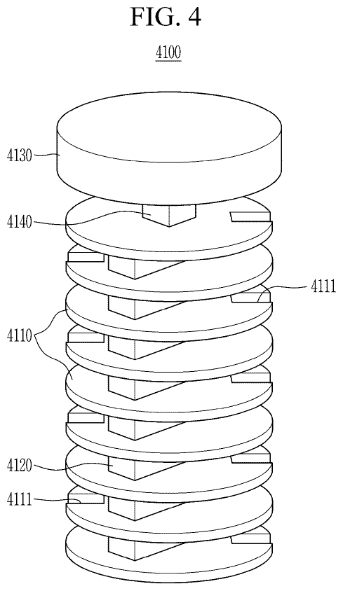

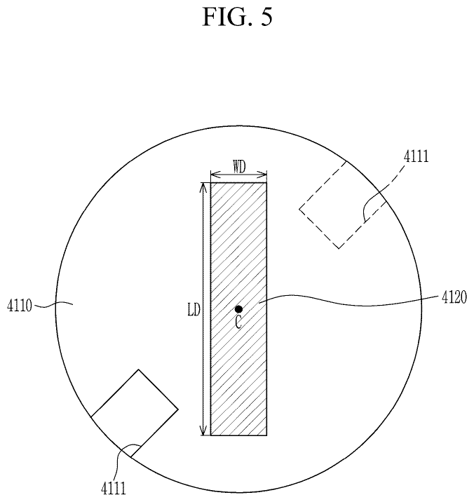

FIG. 2 is a view illustrating the gas mixing module 40 in FIG. 1, FIG. 3 is a view illustrating a module housing 4000 of the gas mixing module 40, FIG. 4 is a view illustrating a gas mixing member 4100 of the gas mixing module 40, and FIG. 5 is a transverse cross-sectional view in a direction perpendicular to the upward/downward direction of a region in which a guide column 4120 is disposed.

With reference to FIGS. 2 to 5, the gas mixing module 40 may include the module housing 4000 and the gas mixing member 4100.

The module housing 4000 may have a preset volume. An accommodation space 4020 is positioned in the module housing 4000. The accommodation space 4020 may have a column shape having a preset length in the upward/downward direction. An upper side of the accommodation space 4020 may be opened toward the outside.

Inflow paths 4011 and 4012 may be positioned in the module housing 4000. Outer ends of the inflow paths 4011 and 4012 are positioned in an outer surface of the module housing 4000, and inner ends of the inflow paths 4011 and 4012 are positioned to be connected to the accommodation space 4020, such that the inflow paths 4011 and 4012 connect the outside of the module housing 4000 and the accommodation space 4020. The inner ends of the inflow paths 4011 and 4012 may be coupled to an upper portion of the accommodation space 4020. The outer ends of the inflow paths 4011 and 4012 may be exposed to the outside through the outer surface (outer side surface) of the module housing 4000. The outer ends of the inflow paths 4011 and 4012 may be positioned above the inner ends of the inflow paths 4011 and 4012. For example, the inflow paths 4011 and 4012 may be inclined to be inclined upward from the outer ends, which are connected to the outside, to the inner ends connected to the accommodation space 4020. The inflow paths 4011 and 4012 may include a first inflow path 4011 and a second inflow path 4012. The first inflow path 4011 and the second inflow path 4012 may be perpendicular to face each other with a central region of the accommodation space 4020 interposed therebetween.

Pipe insertion portions 4015 and 4016 may be positioned in the outer surface of the module housing 4000. The pipe insertion portions 4015 and 4016 may each have a groove structure recessed by a preset depth toward the central region of the module housing 4000. The pipe insertion portions 4015 and 4016 are positioned in regions positioned at the outer ends of the inflow paths 4011 and 4012. The pipe insertion portions 4015 and 4016 may be positioned in the outer surface (outer side surface) of the module housing 4000. Ends of pipes 5001 and 5002, which connect the process gas supply members 51 and 52 and the gas mixing module 40, may be inserted into the pipe insertion portions 4015 and 4016. The pipe insertion portions 4015 and 4016 may include a first pipe insertion portion 4015 and a second pipe insertion portion 4016. An end of a first pipe 5001, which connects the first process gas supply member 51 and the gas mixing module 40, may be inserted into the first pipe insertion portion 4015. Therefore, the first process gas supplied by the first process gas supply member 51 may be introduced into the accommodation space 4020 through the first inflow path 4011.

An end of a second pipe 5002, which connects the second process gas supply member 52 and the gas mixing module 40, may be inserted into the second pipe insertion portion 4016. Therefore, the second process gas supplied by the second process gas supply member 52 may be introduced into the accommodation space 4020 through the second inflow path 4012.

A fastening stepped portion 4021 may be positioned at an upper end of the accommodation space 4020. The fastening stepped portion 4021 may be positioned in a region in which an upper region is larger in area of the accommodation space 4020 based on the direction perpendicular to the upward/downward direction than a lower region. The fastening stepped portion 4021 may be positioned above the inner ends of the inflow paths 4011 and 4012.

A discharge flow path 4030 may be positioned in the module housing 4000. The discharge flow path 4030 may be connected to a lower portion of the accommodation space 4020. A lower end of the discharge flow path 4030 may be exposed to the bottom surface of the module housing 4000 and connected to the outside. The discharge flow path 4030 may include a convergence portion 4031 and a spraying portion 4032.

The convergence portion 4031 may be positioned in an upper portion of the discharge flow path 4030. The convergence portion 4031 may be connected to a lower portion of the accommodation space 4020. A lower end of the convergence portion 4031 may be smaller in area in the direction perpendicular to the upward/downward direction than an upper end of the convergence portion 4031. For example, the area of the convergence portion 4031 in the direction perpendicular to the upward/downward direction may decrease from the upper portion to the lower portion of the convergence portion 4031. In this case, a degree to which the area of the convergence portion 4031 in the direction perpendicular to the upward/downward direction decreases may be linear or non-linear.

The spraying portion 4032 may be positioned below the convergence portion 4031. The spraying portion 4032 may be connected to a lower end of the convergence portion 4031. The area of the spraying portion 4032 in the direction perpendicular to the upward/downward direction may correspond to an area of the lower end of the convergence portion 4031. A lower end of the spraying portion 4032 may be exposed to the bottom surface of the module housing 4000 and connected to the outside.

The gas mixing member 4100 is disposed in the accommodation space 4020, mixes the first and second process gases supplied to the gas mixing module 40 while the first and second process gases flow, and discharges the first and second process gases through the discharge flow path 4030.

The gas mixing member 4100 may include division partition walls 4110, the guide column 4120, and a shield partition wall 4130.

The division partition wall 4110 may have a plate structure having a preset area. At least two or more division partition walls 4110 may be disposed to be spaced apart from one another in the upward/downward direction. FIG. 4 exemplarily illustrates a case in which nine division partition walls 4110 are disposed to be spaced apart from one another at a preset distance in the upward/downward direction. In this case, when the gas mixing member 4100 is disposed in the accommodation space 4020, an upper or lower surface of the division partition wall 4110 may be disposed on a plane perpendicular to the upward/downward direction. In addition, when the gas mixing member 4100 is disposed in the accommodation space 4020, the upper or lower surface of the division partition wall 4110 may be disposed to be inclined with respect to the plane perpendicular to the upward/downward direction.

When the gas mixing member 4100 is disposed in the accommodation space 4020, the division partition walls 4110 divide the accommodation space 4020 in a direction intersecting the upward/downward direction. Therefore, when the gas mixing member 4100 is disposed in the accommodation space 4020, a mixing space 4115 may be positioned between the two division partition walls 4110 that face each other in the upward/downward direction. In addition, when the gas mixing member 4100 is disposed in the accommodation space 4020, the discharge flow path 4030 may be positioned below the division partition wall 4110 disposed at a lowermost side. For example, the division partition wall 4110 may be provided to have an area corresponding to an inner periphery of the accommodation space 4020, such that a wall surface of the accommodation space 4020 and an outer periphery of the division partition wall 4110 may be tightly attached to each other. In addition, the wall surface of the accommodation space 4020 and the outer periphery of the division partition wall 4110 may be coupled to each other by a method such as welding. Therefore, a flow of the process gas may be blocked between the wall surface of the accommodation space 4020 and the outer periphery of the division partition wall 4110.

A mixing flow path 4111, which is directed in the upward/downward direction, may be positioned in the division partition wall 4110. Therefore, a space, which is positioned above the division partition wall 4110, and a space, which is positioned below the division partition wall 4110, may be connected to each other by the mixing flow path 4111.

When the gas mixing member 4100 is disposed in the accommodation space 4020, the mixing flow path 4111 may have a hole structure directed in the upward/downward direction and formed in the division partition wall 4110 disposed to divide the accommodation space 4020. For example, as illustrated in FIG. 4, the mixing flow path 4111 may have a groove structure recessed from the outer periphery of the division partition wall 4110 toward a central region of the division partition wall 4110. Therefore, when the gas mixing member 4100 is disposed in the accommodation space 4020, the wall surface of the accommodation space 4020 is positioned on the outer periphery of the division partition wall 4110, such that the mixing flow path 4111 may have a hole structure.

The mixing flow paths 4111, which are respectively positioned in the two division partition walls 4110 adjacent to each other in the upward/downward direction, may be positioned in regions that face each other with a center axis C (hereinafter, referred to as a ‘center axis’) interposed therebetween, and the center axis C passes through the central region of the division partition wall 4110 and is directed in the upward/downward direction. For example, the mixing flow paths 4111, which are respectively positioned in the two division partition walls 4110 adjacent to each other in the upward/downward direction, may be positioned to face each other with the center axis C interposed therebetween.

The guide column 4120 is disposed between the two division partition walls 4110 adjacent to each other in the upward/downward direction. The guide column 4120 may protrude upward from the upper surface of the division partition wall 4110 disposed at the lower side between the two division partition walls 4110 adjacent to each other in the upward/downward direction. An upper portion of the guide column 4120 may be connected to the division partition wall 4110 disposed at the upper side between the two division partition walls 4110 adjacent to each other in the upward/downward direction. Therefore, the two division partition walls 4110, which are adjacent to each other in the upward/downward direction, may be connected to each other by the guide column 4120.

The guide column 4120 may have a preset length in a first direction LD intersecting the upward/downward direction. The first direction LD may be referred to as a longitudinal direction LD of the guide column 4120. In addition, the guide column 4120 may have a preset width in a second direction WD intersecting the upward/downward direction and the first direction LD. The second direction WD may be referred to as a width direction WD of the guide column 4120. The length of the guide column 4120 may be larger than the width of the guide column 4120.

The guide column 4120 may be disposed in the central region of the division partition wall 4110. Two opposite ends of the guide column 4120 based on the longitudinal direction LD may be disposed inward of the outer periphery of the division partition wall 4110 toward the central region of the division partition wall 4110. That is, when the gas mixing member 4100 is disposed in the accommodation space 4020, the two opposite ends of the guide column 4120 based on the longitudinal direction LD may be disposed to be spaced apart from the wall surface of the accommodation space 4020. Therefore, spaces, through which the process gases may flow, may be formed outside the two opposite ends of the guide column 4120 based on the longitudinal direction LD.

The longitudinal direction LD of the guide column 4120 may be inclined with respect to the direction in which the mixing flow paths 4111, which are respectively positioned in the two division partition walls 4110 adjacent to each other in the upward/downward direction, face each other. In addition, the two opposite ends of the guide column 4120 based on the longitudinal direction LD may be positioned so that distances, by which the two opposite ends of the guide column 4120 are spaced apart from the mixing flow paths 4111, are different from each other.

The shield partition wall 4130 may be disposed at an upper end of the gas mixing member 4100. The shield partition wall 4130 may have a structure corresponding to the upper end of the accommodation space 4020. When the gas mixing member 4100 is disposed in the accommodation space 4020, the shield partition wall 4130 may be disposed at an upper end of the accommodation space 4020 to shield the accommodation space 4020, which is positioned below the shield partition wall 4130, from the outside. When the gas mixing member 4100 is disposed in the accommodation space 4020, the shield partition wall 4130 may be disposed on the fastening stepped portion 4021. When the gas mixing member 4100 is disposed in the accommodation space 4020, an inflow space 4116 may be positioned between a lower surface of the shield partition wall 4130 and an upper surface of the division partition wall 4110 disposed at the uppermost side among the plurality of division partition walls 4110.

The shield partition wall 4130 and the division partition wall 4110, which is disposed at the uppermost side among the plurality of division partition walls 4110, may be connected by a connection column 4140. The connection column 4140 may be disposed in the central region of the division partition wall 4110.

When the gas mixing member 4100 is disposed in the accommodation space 4020 of the module housing 4000, a flow path, in which the process gases may be mixed while flowing and then sprayed into the chamber 10, is positioned inside the module housing 4000. That is, in the module housing 4000, at least two or more division partition walls 4110 may be disposed to be spaced apart from one another at preset distances in the upward/downward direction. Therefore, the mixing space 4115 may be positioned between the two division partition walls 4110 facing each other in the upward/downward direction in the module housing 4000. In addition, the guide column 4120 may be disposed between the two division partition walls 4110 adjacent to each other in the upward/downward direction. In addition, the discharge flow path 4030 may be positioned below the division partition wall 4110 disposed at the lowermost side. Further, the mixing flow path 4111, which is directed in the upward/downward direction, may be positioned in the division partition wall 4110. In addition, the inflow space 4116 may be positioned above the division partition wall 4110 disposed at the uppermost side in the module housing 4000. Further, the first inflow path 4011 and the second inflow path 4012, which connect the outside and the inflow space 4116, may be positioned in the module housing 4000.

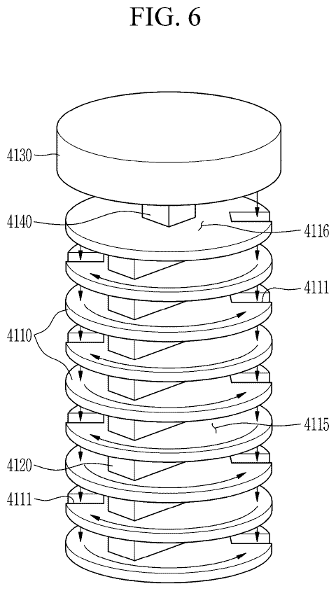

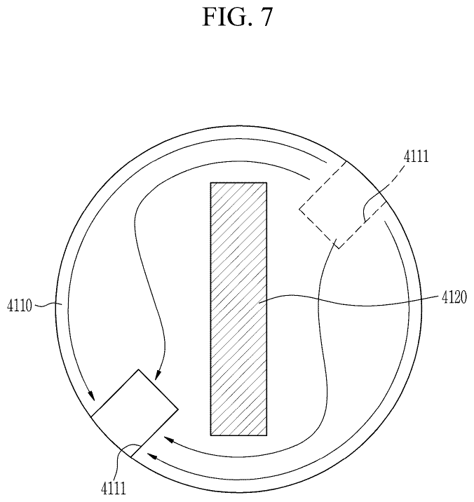

FIG. 6 is a view illustrating a flow state of the process gas occurring around the gas mixing member 4100 when the process gas is supplied to the gas mixing module 40 (gas mixer), and FIG. 7 is a view illustrating a flow state of the process gas in a cross-section corresponding to FIG. 5.

Hereinafter, a process of mixing the first and second process gases when the process gases are supplied to the gas mixing module 40 will be described with reference to FIGS. 6 and 7.

The first process gas, which is supplied by the first process gas supply member 51, is introduced into the inflow space 4116 through the first inflow path 4011. The second process gas, which is supplied by the second process gas supply member 52, is introduced into the inflow space 4116 through the second inflow path 4012. Thereafter, the process gases flow downward while sequentially passing through the mixing spaces 4115 through the mixing flow paths 4111 positioned in the division partition walls 4110. Thereafter, the process gases may be supplied into the chamber 10 through the discharge flow path 4030.

In case that the first and second process gases flow while forming laminar flows, the first and second process gases flow while forming a boundary therebetween, and the first and second process gases are not effectively mixed. The laminar flow is maintained over a long section in case that a shape of a flow path, through which the process gases flow, is constant or a shape of a flow path changes linearly.

In contrast, the substrate processing apparatus 1 according to the one or more embodiments includes a section in which a shape of a flow path through which the process gases flow changes non-linearly. Specifically, in the substrate processing apparatus 1 according to the one or more embodiments, the shape of the flow path, through which the process gases flow, changes non-linearly in a section in which the mixing flow paths 4111 are positioned. That is, in a section in which the process gases are introduced into the mixing flow paths 4111, a shape of the flow path, through which the process gases flow, and a direction, in which the process gases flow, are changed rapidly. In addition, in a section in which the process gases are discharged from the mixing flow paths 4111, a shape of the flow path, through which the process gases flow, and a direction, in which the process gases flow, are changed rapidly. Therefore, the process gases rapidly form turbulent flows in the section including the mixing flow paths 4111, such that the first and second process gases are effectively mixed.

In the substrate processing apparatus 1 according to the one or more embodiments, two paths, through the process gases flow in the mixing spaces 4115, are formed by the guide columns 4120. In this case, the flow paths for the process gases formed at two opposite sides of the guide columns 4120 may be asymmetric. Specifically, the longitudinal direction LD of the guide column 4120 may be inclined with respect to the direction in which the mixing flow paths 4111, which are respectively positioned in the division partition walls 4110 adjacent to each other in the upward/downward direction, face each other. Further, the distances, by which the two opposite ends of the guide column 4120 based on the longitudinal direction LD are spaced apart from the mixing flow paths 4111, may be different from each other. In other words, one or more ends of the guide column in the longitudinal direction may be closer to one of the mixing flow paths than to another of the mixing flow paths. Therefore, the flow paths formed at the two opposite sides of the guide column 4120 have different areas depending on the region. In addition, an area of the flow path is rapidly changed in a region adjacent to an end of the guide column 4120 based on the longitudinal direction LD. Therefore, the process gases flowing in the mixing space 4115 may form turbulent flows.

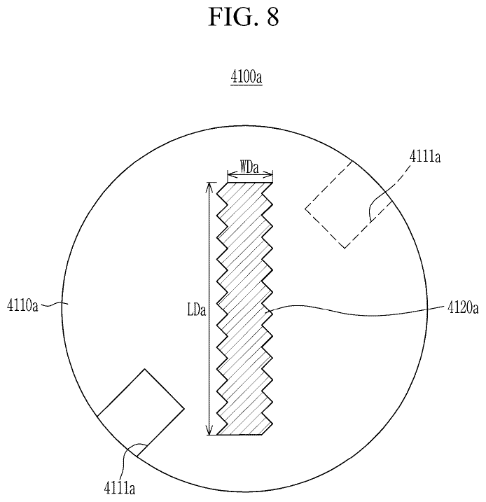

FIG. 8 is a transverse cross-sectional view of a region in which a guide column 4120a of a gas mixing member 4100a according to one or more embodiments is disposed.

With reference to FIG. 8, the guide column 4120a is disposed between two division partition walls 4110a adjacent to each other in the upward/downward direction. The guide column 4120a may protrude upward from an upper surface of the division partition wall 4110a disposed at a lower side between the two division partition walls 4110a disposed adjacent to each other in the upward/downward direction. An upper portion of the guide column 4120a may be connected to the division partition wall 4110a disposed at an upper side between the two division partition walls 4110a disposed adjacent to each other in the upward/downward direction. Therefore, the two division partition walls 4110a, which are adjacent to each other in the upward/downward direction, may be connected to each other by the guide column 4120a.

The guide column 4120a may have a preset length in a first direction LDa intersecting the upward/downward direction. The first direction LDa may be referred to as a longitudinal direction LDa of the guide column 4120a. In addition, the guide column 4120a may have a preset width in a second direction WDa intersecting the upward/downward direction and the first direction LDa. The second direction WDa may be referred to as a width direction WDa of the guide column 4120a. The length of the guide column 4120a may be larger than the width of the guide column 4120a.

The guide column 4120a may be disposed in a central region of the division partition wall 4110a. Two opposite ends of the guide column 4120a based on the longitudinal direction LDa may be disposed inward of an outer periphery of the division partition wall 4110a toward the central region of the division partition wall 4110a. That is, when the gas mixing member 4100a is disposed in the accommodation space 4020, the two opposite ends of the guide column 4120a based on the longitudinal direction LDa may be disposed to be spaced apart from the wall surface of the accommodation space 4020. Therefore, spaces, through which the process gases may flow, may be formed outside the two opposite ends of the guide column 4120a based on the longitudinal direction LDa.

The longitudinal direction LDa of the guide column 4120a may be inclined with respect to the direction in which the mixing flow paths 4111a, which are respectively disposed in the division partition walls 4110a adjacent to each other in the upward/downward direction, face each other. In addition, the two opposite ends of the guide column 4120a based on the longitudinal direction LDa may be disposed so that distances, by which the two opposite ends of the guide column 4120a are spaced apart from the mixing flow paths 4111a, are different from each other.

The outer surface of the guide column 4120a may have a concave-convex structure. That is, it may be understood that protrusions are positioned on the outer surface of the guide column 4120a, grooves are positioned on the outer surface of the guide column 4120a, or protrusions and grooves are positioned on the outer surface of the guide column 4120a. The outer surfaces of the guide columns 4120a, which face each other in the width direction WDa of the guide column 4120a, may have the concave-convex structure. In addition, the outer surfaces of the guide columns 4120a, which face each other in the longitudinal direction LDa of the guide column 4120a, may have the concave-convex structure. FIG. 8 exemplarily illustrates that the outer surfaces of the guide columns 4120a, which face each other in the width direction WDa of the guide column 4120a, have the concave-convex structure.

Because the structure of the gas mixing member 4100a is identical or similar to that of the gas mixing member 4100 described above with reference to FIGS. 4 and 5, except for the structure of the guide column 4120a, a repeated description will be omitted.

The outer surface of the gas mixing member 4100a according to one or more embodiments has the concave-convex structure. Therefore, during the process in which the process gases flow, the process gases may more effectively form turbulent flows in a region adjacent to the outer surface of the guide column 4120a.

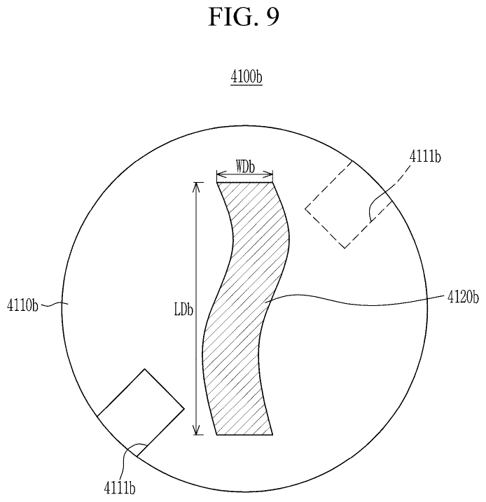

FIG. 9 is a transverse cross-sectional view of a region in which a guide column 4120b of a gas mixing member 4100b according to still one or more embodiments is disposed.

With reference to FIG. 9, the guide column 4120b is disposed between two division partition walls 4110b adjacent to each other in the upward/downward direction. The guide column 4120b may protrude upward from an upper surface of the division partition wall 4110b disposed at a lower side between the two division partition walls 4110b disposed adjacent to each other in the upward/downward direction. An upper portion of the guide column 4120b may be connected to the division partition wall 4110b disposed at an upper side between the two division partition walls 4110b disposed adjacent to each other in the upward/downward direction. Therefore, the two division partition walls 4110b, which are adjacent to each other in the upward/downward direction, may be connected to each other by the guide column 4120b.

The guide column 4120b may have a preset length in a first direction LDb intersecting the upward/downward direction. The first direction LDb may be referred to as a longitudinal direction LDb of the guide column 4120b. In addition, the guide column 4120b may have a preset width in a second direction WDb intersecting the upward/downward direction and the first direction LDb. The second direction WDb may be referred to as a width direction WDb of the guide column 4120b. The length of the guide column 4120b may be larger than the width of the guide column 4120b.

The guide column 4120b may be disposed in a central region of the division partition wall 4110b. Two opposite ends of the guide column 4120b based on the longitudinal direction LDb may be disposed inward of an outer periphery of the division partition wall 4110b toward the central region of the division partition wall 4110b. That is, when the gas mixing member 4100b is disposed in the accommodation space 4020, the two opposite ends of the guide column 4120b based on the longitudinal direction LDb may be disposed to be spaced apart from the wall surface of the accommodation space 4020. Therefore, spaces, through which the process gases may flow, may be formed outside the two opposite ends of the guide column 4120b based on the longitudinal direction LDb.

The longitudinal direction LDb of the guide column 4120b may be inclined with respect to the direction in which the mixing flow paths 4111b, which are respectively positioned in the division partition walls 4110b adjacent to each other in the upward/downward direction, face each other. In addition, the two opposite ends of the guide column 4120b based on the longitudinal direction LDb may be disposed so that distances, by which the two opposite ends of the guide column 4120b are spaced apart from the mixing flow paths 4111b, are different from each other.

At least a partial section between the two opposite ends of the guide column 4120b based on the longitudinal direction LDb may be non-linear. For example, the guide column 4120b may have a curved structure in at least a partial section between the two opposite ends based on the longitudinal direction LDb. In addition, the guide column 4120b may also have a structure bent at an angle of 90° or less in at least a partial section between the two opposite ends based on the longitudinal direction LDb. FIG. 9 exemplarily illustrates that the guide column 4120b has the curved structure between the two opposite ends based on the longitudinal direction LDb.

Because the structure of the gas mixing member 4100b is identical or similar to that of the gas mixing member 4100 described above with reference to FIGS. 4 and 5, except for the structure of the guide column 4120b, a repeated description will be omitted.

In addition, the outer surface of the guide column 4120b may have a concave-convex structure identical or similar to that of the gas mixing member 4100a described above with reference to FIG. 8, and a repeated description will be omitted.

At least a partial section between the two opposite ends based on the longitudinal direction LDb of the guide column 4120b of the gas mixing member 4100b according to one or more embodiments may be non-linear. Therefore, it is possible to adjust the shapes of the flow paths for the process gases formed at the two opposite sides of the guide column 4120b so that the turbulent flows may be effectively formed.

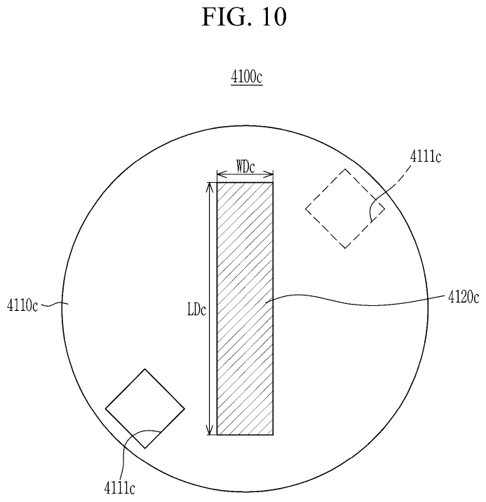

FIG. 10 is a transverse cross-sectional view of a region in which a guide column 4120c of a gas mixing member 4100c according to yet one or more embodiments is disposed.

With reference to FIG. 10, a mixing flow path 4111c, which is directed in the upward/downward direction, may be positioned in the division partition wall 4110c. The mixing flow path 4111c may be positioned to be spaced apart from the outer periphery of the division partition wall 4110c at a preset distance toward the central region of the division partition wall 4110c. The mixing flow path 4111c may have a hole structure formed in the division partition wall 4110c and directed in the upward/downward direction.

The structure of the gas mixing member 4100c may be identical or similar to that of the gas mixing member 4100 described above with reference to FIGS. 4 and 5, the gas mixing member 4100a described above with reference to FIG. 8, or the gas mixing member 4100b described above with reference to FIG. 9, except for the structure of the mixing flow path 4111c, and a repeated description will be omitted.

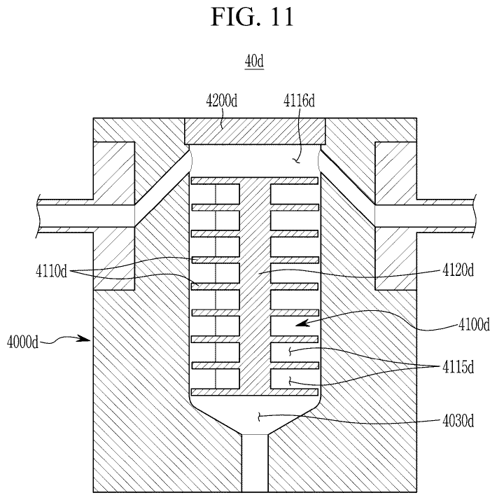

FIG. 11 is a view illustrating a gas mixing module 40d according to one or more embodiments.

With reference to FIG. 11, the gas mixing module 40d according to one or more embodiments may include a module housing 4000d, a gas mixing member 4100d, and a shield partition wall 4200d.

Because the structure of the module housing 4000d is identical or similar to the structure of the module housing 4000 described above with reference to FIGS. 2 and 3, a repeated description will be omitted.

The gas mixing member 4100d may include division partition walls 4110d and guide columns 4120d. The structures of the division partition wall 4110d and the guide column 4120d may be identical or similar to those of the gas mixing member 4100 described above with reference to FIGS. 4 and 5, the gas mixing member 4100a described above with reference to FIG. 8, the gas mixing member 4100b described above with reference to FIG. 9, or the gas mixing member 4100c described above with reference to FIG. 10, and a repeated description will be omitted.

The structure of the shield partition wall 4200d may be identical or similar to the structure of the shield partition wall 4130 of the gas mixing member 4100 described above with reference to FIGS. 4 and 5, except that the connection column 4140 of the gas mixing member 4100 described above with reference to FIGS. 4 and 5 is excluded, and the shield partition wall 4200d is disposed to be spaced apart from the gas mixing member 4100d. Therefore, a repeated description will be omitted.

The shield partition wall 4200d may be disposed to be spaced apart from the division partition wall 4110d disposed at the uppermost side, such that an inflow space 4116d may be positioned between a lower surface of the shield partition wall 4200d and an upper surface of the division partition wall 4110d disposed at the uppermost side.

When the gas mixing member 4100d and the shield partition wall 4200d are disposed in the module housing 4000d, a flow path, in which the process gases may be mixed while flowing and then sprayed into the chamber 10, is positioned inside the module housing 4000d. That is, in the module housing 4000d, at least two or more division partition walls 4110d may be disposed to be spaced apart from one another at preset distances in the upward/downward direction. Therefore, a mixing space 4115d may be positioned between the two division partition walls 4110d facing each other in the upward/downward direction in the module housing 4000d. In addition, a guide column 4120d may be disposed between the two division partition walls 4110d adjacent to each other in the upward/downward direction. In addition, a discharge flow path 4030d may be positioned below the division partition wall 4110d disposed at the lowermost side. In addition, an inflow space 4116d may be positioned above the division partition wall 4110d disposed at the uppermost side in the module housing 4000d.

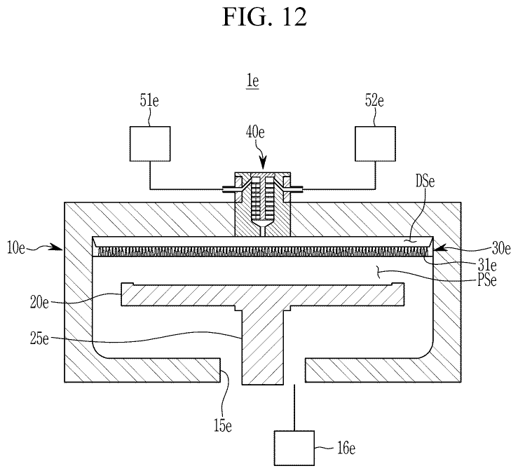

FIG. 12 is a view illustrating a substrate processing apparatus 1e according to one or more embodiments.

With reference to FIG. 12, the substrate processing apparatus 1e according to one or more embodiments may include a chamber 10e, a support member 20e, a shower head 30e, and a gas mixing module 40e.

The substrate processing apparatus 1e processes a substrate by using process gases. For example, the substrate processing apparatus 1e may perform a process of removing a natural oxide film from the substrate by using reactivity of the process gas. The substrate may be a wafer or the like used to manufacture a semiconductor element.

The chamber 10e provides therein a process space PSe in which a substrate processing process is performed. The chamber 10e may be made of metal. For example, the chamber 10e may be made of aluminum. The chamber 10e may be grounded.

An exhaust hole 15e may be positioned at one side of the chamber 10e. The exhaust hole 15e may be positioned in a lower region of the chamber 10e. The exhaust hole 15e may be positioned in the lower wall of the chamber 10e. Reaction by-products, which are generated during a processing procedure, and gases, which remain in the internal space of the chamber 10e, may be discharged to the outside through the exhaust hole 15e. The pressure in the chamber 10e may be lowered to predetermined pressure by an exhaust process. An exhaust member 16e may be connected to the exhaust hole 15e. The exhaust member 16e applies negative pressure for discharging gases in the chamber 10e. In addition, the exhaust member 16e may adjust a flow rate of the gas to be discharged through the exhaust hole 15e. The exhaust member 16e may include at least one pump. In addition, the exhaust member 16e may include a valve or the like and adjust a flow rate of the gas to be discharged through the exhaust hole 15e in accordance with an opening degree of the valve.

The support member 20e is disposed in the chamber 10e. The support member 20e supports the substrate. For example, the support member 20e may be connected and fixed to a support shaft 25e. The support shaft 25e may be provided such that a longitudinal direction thereof is directed toward the upward/downward direction, such that the support shaft 25e is disposed to pass through the exhaust hole 15e. An upper portion of the support shaft 25e may be connected to the support member 20e in the chamber 10e. The exhaust hole 15e may be provided to be larger than an outer periphery of the support shaft 25e, such that the gas in the chamber 10e may be discharged through a space positioned between the support shaft 25e and the exhaust hole 15e.

The support member 20e may be configured to cool the substrate. For example, a cooling flow path may be positioned in the support member 20e. Therefore, the support member 20e may be cooled by a refrigerant flowing through the cooling flow path, such that the substrate positioned on the support member 20e may be cooled.

The bottom surface of the shower head 30e is disposed to be directed toward the inside of the chamber 10e. The shower head 30e may disperse and spray the process gas, which is supplied into the chamber 10e, toward the process space PSe positioned above the support member 20e. The shower head 30e may be fixed to the chamber 10e. For example, the shower head 30e may be connected to an inner wall of the chamber 10e.

A process gas flow path 31e may be positioned in the shower head 30e. The process gas flow path 31e may be connected to the bottom surface of the shower head 30e. The process gas flow path 31e may include hole structures directed in the upward/downward direction. In addition, the process gas flow path 31e may also include a section that connects the hole structures directed in the upward/downward direction.

The upper surface of the shower head 30e is disposed to be spaced apart from the bottom surface of the upper wall of the chamber 10e, such that a gas distribution space DSe may be positioned between the upper surface of the shower head 30e and the bottom surface of the upper wall of the chamber 10e. The gas distribution space DSe may be connected to the process gas flow path 31e. In addition, the upper surface of the shower head 30e and the bottom surface of the upper wall of the chamber 10e may be disposed to be in contact with each other.

The gas mixing module 40e may be connected to the chamber 10e. For example, the gas mixing module 40e may be connected to a central region of the upper wall of the chamber 10e. The gas mixing module 40e is disposed to penetrate the chamber 10e, such that a bottom surface of the gas mixing module 40e may be disposed to be exposed to the inside of the chamber 10e.

The gas mixing module 40e sprays the process gas into the chamber 10e. The process gas sprayed from the gas mixing module 40e may be supplied to the process space PSe through the gas distribution space DSe and the process gas flow path 31e of the shower head 30e. In addition, in case that the gas distribution space DSe is excluded, the process gas sprayed from the gas mixing module 40e may be introduced directly into the process gas flow path 31e of the shower head 30e.

The gas mixing module 40e may be connected to process gas supply members 51e and 52e. The process gas supply members 51e and 52e may include a first process gas supply member 51e and a second process gas supply member 52e. Because the process gas supply members 51e and 52e are identical or similar to the process gas supply members 51 and 52 described above with reference to FIG. 1, a repeated description will be omitted.

Because the gas mixing module 40e is identical or similar to those described above with reference to FIGS. 2 to 11, a repeated description will be omitted.

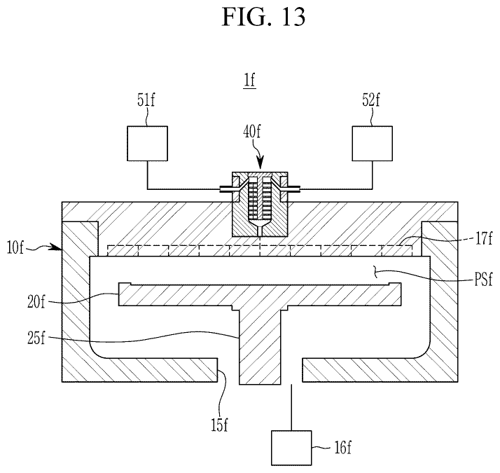

FIG. 13 is a view illustrating a substrate processing apparatus 1f according to still one or more embodiments.

With reference to FIG. 13, the substrate processing apparatus 1f according to still one or more embodiments may include a chamber 10f, a support member 20f, and a gas mixing module 40f.

The substrate processing apparatus 1f processes a substrate by using process gases. For example, the substrate processing apparatus 1f may perform a process of removing a natural oxide film from the substrate by using reactivity of the process gas. The substrate may be a wafer or the like used to manufacture a semiconductor element.

The chamber 10f provides therein a process space PSf in which a substrate processing process is performed. The chamber 10f may be made of metal. For example, the chamber 10f may be made of aluminum. The chamber 10f may be grounded.

An exhaust hole 15f may be positioned at one side of the chamber 10f. The exhaust hole 15f may be positioned in a lower region of the chamber 10f. The exhaust hole 15f may be positioned in the lower wall of the chamber 10f. Reaction by-products, which are generated during a processing procedure, and gases, which remain in the internal space of the chamber 10f, may be discharged to the outside through the exhaust hole 15f. The pressure in the chamber 10f may be lowered to predetermined pressure by an exhaust process. An exhaust member 16f may be connected to the exhaust hole 15f. The exhaust member 16f applies negative pressure for discharging gases in the chamber 10f. In addition, the exhaust member 16f may adjust a flow rate of the gas to be discharged through the exhaust hole 15f. The exhaust member 16f may include at least one pump. In addition, the exhaust member 16f may include a valve or the like and adjust a flow rate of the gas to be discharged through the exhaust hole 15f in accordance with an opening degree of the valve.

The support member 20f is disposed in the chamber 10f. The support member 20f supports the substrate. For example, the support member 20f may be connected and fixed to a support shaft 25f. The support shaft 25f may be provided such that a longitudinal direction thereof is directed toward the upward/downward direction, such that the support shaft 25f is disposed to pass through the exhaust hole 15f. An upper portion of the support shaft 25f may be connected to the support member 20f in the chamber 10f. The exhaust hole 15f may be provided to be larger than an outer periphery of the support shaft 25f, such that the gas in the chamber 10f may be discharged through a space positioned between the support shaft 25f and the exhaust hole 15f.

The support member 20f may be configured to cool the substrate. For example, a cooling flow path may be positioned in the support member 20f. Therefore, the support member 20f may be cooled by a refrigerant flowing through the cooling flow path, such that the substrate positioned on the support member 20f may be cooled.

A process gas flow path 17f may be positioned in an upper wall of the chamber 10f. The process gas flow path 17f may be connected to a bottom surface of the upper wall of the chamber 10f. The process gas flow path 17f may include hole structures directed in the upward/downward direction. In addition, the process gas flow path 17f may also include a section that connects the hole structures directed in the upward/downward direction. With the process gas flow path 17f, the upper wall of the chamber 10f may serve as a shower head.

The gas mixing module 40f may be connected to the chamber 10f. For example, the gas mixing module 40f may be connected to a central region of the upper wall of the chamber 10f. The gas mixing module 40f may be connected to the process gas flow path 17f.

The gas mixing module 40f sprays the process gas into the chamber 10f. The process gases sprayed from the gas mixing module 40f may be supplied into the chamber 10f through the process gas flow path 17f.

The gas mixing module 40f may be connected to process gas supply members 51f and 52f. The process gas supply members 51f and 52f may include a first process gas supply member 51f and a second process gas supply member 52f. Because the process gas supply members 51f and 52f are identical or similar to the process gas supply members 51 and 52 described above with reference to FIG. 1, a repeated description will be omitted.

Because the gas mixing module 40f is identical or similar to those described above with reference to FIGS. 2 to 11, a repeated description will be omitted.

Although the one or more embodiments of the present disclosure have been described in detail above, the right scope of the present disclosure is not limited thereto, and it should be construed that many variations and modifications made by those skilled in the art using the basic concept of the present disclosure, which is defined in the following claims, will also belong to the right scope of the present disclosure.

### DESCRIPTION OF SYMBOLS

10: Chamber
15: Exhaust hole
16: Exhaust member
20: Support member
25: Support shaft
30: Shower head
40: Gas mixing module
51: First process gas supply member
52: Second process gas supply member
4000: Module housing
4011: First inflow path
4012: Second inflow path
4015: First pipe insertion portion
4016: Second pipe insertion portion
4020: Accommodation space
4021: Fastening stepped portion
4030: Discharge flow path
4110: Division partition wall
4111: Mixing flow path
4115: Mixing space
4116: Inflow space
4120: Guide column
4130: Shield partition wall
4140: Connection column

What is claimed is:

1. A substrate processing apparatus comprising:
a chamber;
a support in the chamber and configured to support a substrate; and
a gas mixer connected to the chamber and configured to spray a process gas into the chamber, wherein the gas mixer comprises:
division partition walls spaced apart in a vertical direction; and
mixing flow paths oriented in the vertical direction in the division partition walls.

2. The substrate processing apparatus of claim 1, wherein:
a division partition wall among the division partition walls has a plate structure having a preset area, and
at least one of the mixing flow paths has a hole structure oriented in the vertical direction.

3. The substrate processing apparatus of claim 1, wherein the gas mixer further comprises:
a center axis passing through centers of the division partition walls and oriented in the vertical direction.

4. The substrate processing apparatus of claim 1, wherein the gas mixer further comprises:
a guide column between the division partition walls.

5. The substrate processing apparatus of claim 4, wherein:
the guide column comprises a longitudinal direction intersecting the vertical direction and a width direction intersecting the vertical direction and the longitudinal direction, and
a length of the guide column in the longitudinal direction is larger than a width of the guide column in the width direction.

6. The substrate processing apparatus of claim 5, wherein:
an end of the guide column in the longitudinal direction is closer to one of the mixing flow paths than to another of the mixing flow paths.

7. The substrate processing apparatus of claim 1, wherein:
the gas mixer has a discharge flow path below a lowermost division partition wall among the division partition walls.

8. The substrate processing apparatus of claim 1, wherein:
the gas mixer comprises an inflow space above an uppermost division partition wall among the division partition walls.

9. The substrate processing apparatus of claim 8, wherein the gas mixer further comprises:
a first inflow path which connects an outside and the inflow space; and
a second inflow path which connects the outside and the inflow space.

10. A substrate processing apparatus comprising:
a chamber;
a support in the chamber and configured to support a substrate; and
a gas mixer connected to the chamber and configured to spray a process gas into the chamber, wherein the gas mixer comprises:
a housing having an accommodation space positioned therein; and
a gas mixing member disposed in the accommodation space, wherein the gas mixing member comprises:
division partition walls spaced apart in a vertical direction; and
a guide column connecting the division partition walls.

11. The substrate processing apparatus of claim 10, wherein:
wherein mixing flow paths oriented in the vertical direction are in the division partition walls.

12. The substrate processing apparatus of claim 11, wherein:
at least one of the mixing flow paths has a groove structure recessed from an outer periphery of a division partition wall of the division partition walls toward a central region of the division partition wall.

13. The substrate processing apparatus of claim 11, wherein:
at least one of the mixing flow paths has a hole structure oriented in the vertical direction.

14. The substrate processing apparatus of claim 11, wherein:
the gas mixer further comprises a center axis passing through centers of the division partition walls and oriented in the vertical direction,
the guide column comprises a longitudinal direction intersecting the vertical direction,
the mixing flow paths are in two adjacent division partition walls in the vertical direction among the division partition walls, and
an end of the guide column in the longitudinal direction is closer to one of the mixing flow paths than to another of the mixing flow paths.

15. The substrate processing apparatus of claim 10, wherein the gas mixer further comprises:
a shield partition wall at an upper end of the gas mixing member; and
a connection column connecting the shield partition wall and an uppermost division partition wall among the division partition walls.

16. The substrate processing apparatus of claim 10, wherein the gas mixer further comprises:
a discharge flow path connected to a lower portion of the accommodation space in the housing.

17. The substrate processing apparatus of claim 10, wherein the gas mixer further comprises:
an inflow path connecting an outside of the housing and an upper portion of the accommodation space in the housing.

18. The substrate processing apparatus of claim 17, wherein:
an inner end of the inflow path, which is connected to the accommodation space, is above an outer end of the inflow path connected to the outside.

19. A substrate processing apparatus comprising:
a chamber;
a support in the chamber and configured to support a substrate;
a gas mixer connected to the chamber and configured to spray a process gas into the chamber;
a first process gas supply connected to the gas mixer and configured to supply a first process gas; and
a second process gas supply connected to the gas mixer and configured to supply a second process gas,
wherein the gas mixer comprises:
a housing having an accommodation space therein; and
a gas mixing member in the accommodation space, wherein the gas mixing member comprises:
division partition walls spaced apart in a vertical direction; and
a guide column connecting the division partition walls.

20. The substrate processing apparatus of claim 19, wherein:
the gas mixer further comprises mixing flow paths oriented in the vertical direction in the division partition walls,
the guide column comprises a longitudinal direction intersecting the vertical direction, and
an end of the guide column in the longitudinal direction is closer to one of the mixing flow paths than to another of the mixing flow paths.
